(19) United States
(12) Patent Application Publication
(10) Pub. No.: US 2016/0079604 A1
(43) Pub. Date: Mar. 17, 2016

(54) CATALYST ELECTRODES AND METHOD OF MAKING IT

(71) Applicant: 3M INNOVATIVE PROPERTIES COMPANY, Saint Paul, MN (US)

(72) Inventors: Radoslav ATANASOSKI, Oakland, CA (US); Ljiljana L. ATANASOSKA, Oakland, CA (US); Gregory M. HAUGEN, Edina, MN (US); Andrew M. ARMSTRONG, Stillwater, MN (US); Dennis F. VAN DER VLIET, Minneapolis, MN (US); Jimmy L. WONG, St. Paul, MN (US)

(73) Assignee: 3M Company, Saint Paul, MN (US)

(21) Appl. No.: 14/784,523

(22) PCT Filed: Apr. 21, 2014
(86) PCT No.: PCT/US14/34757

§ 371 Date: Oct. 14, 2015

Related U.S. Application Data
(60) Provisional application No. 61/815,015, filed on Apr. 23, 2013.
(60) Provisional application No. 61/863,015, filed on Aug. 7, 2013.

(51) Int. Cl. H01M 4/92; C23C 14/30; H01M 4/88

(52) U.S. Cl. CPC H01M 4/92; H01M 4/8871; C23C 14/30

(57) ABSTRACT

Fuel cell anodes comprising (a) a catalyst comprising Pt, (b) an oxygen evolution reaction catalyst, and (c) at least one of Au, a refractory metal (e.g., at least one of Hf, Nb, Os, Re, Rh, Ta, Ti, W, or Zr), a refractory metal oxide, a refractory metal boride, a refractory metal carbide, a refractory metal nitride, or a refractory metal silicide. The fuel cell anodes are useful in fuel cells.

### CROSS REFERENCE TO RELATED APPLICATIONS

This application claims the benefit of U.S. Provisional Patent Application Nos. 61/815015, filed Apr. 23, 2013 and 61/863015 filed Aug. 7, 2013, the disclosures of which are incorporated by reference herein in their entireties.

This invention was made with Government support under Cooperative Agreement DE-EE0000456 awarded by DOE. The Government has certain rights in this invention.

### BACKGROUND

A proton exchange membrane (PEM) fuel cell converts electrochemical energy released during the hydrogen and oxygen electrode reactions into electrical energy. A stream of hydrogen is delivered to the anode side of the membrane electrode assembly (MEA). The half-cell reaction at the anode, hydrogen oxidation reaction (HOR), splits hydrogen into protons and electrons. The newly generated protons permeate through the polymer electrolyte membrane to the cathode side. The electrons travel along an external load circuit to the cathode side of the MEA, thus creating the current output of the fuel cell. Meanwhile, a stream of oxygen is delivered to the cathode side of the MEA. At the cathode side oxygen molecules are reduced by the electrons arriving through the external circuit and combined with the protons permeating through the polymer electrolyte membrane to form water molecules. This cathodic half-cell reaction is an oxygen reduction reaction (ORR). Both half cell reactions are typically catalyzed by platinum based materials. Each cell produces about 1.1 volt, so to reach the desired voltage for a particular application the cells are combined to produce stacks. Each cell is divided with bipolar plates which while separating them provide a hydrogen fuel distribution channel, as well as a method of extracting the current. PEM fuel cells are considered to have the highest energy density of all the fuel cells, and due to the nature of the reaction have the quickest start up time (less than 1 second). Therefore, they tend to be favored for applications such as vehicles, portable power, and backup power applications.

A PEM fuel cell operating in an automotive application typically undergoes thousands of start-up/shut-down events over multiple years of operation. During these transient periods of repeated fuel cell start up/shut down cycles, and also during other abnormal fuel cell operation conditions (e.g., a cell reversal caused by local fuel starvation), the electrodes can be driven temporarily to relatively high positive potentials significantly beyond their normal operational values and beyond the thermodynamic stability of water (i.e., >1.23 V). These transient high potential pulses can lead to degradation of the catalyst layer. Corrosion of the carbon support can also occur for carbon supported catalysts.

Incorporation of oxygen evolution reaction (OER) catalysts to favor water electrolysis over carbon corrosion or catalyst degradation/dissolution is a relatively new material based strategy for achieving fuel cell durability during transient conditions by reducing cell voltage. Ru has been observed to exhibit excellent OER activity but it is preferably stabilized. Ir is well known for being able to stabilize Ru, while Ir itself has been observed to exhibit good OER activity. Although not wanting to be bound by theory, it is believed that for a successful incorporation of OER catalysts, it is desired to prevent them from blocking and affecting Pt hydrogen oxidation reaction (HOR).

Before start-up, the anode flow field is typically filled with air. During the fuel cell start-up, the gas switches from air to hydrogen resulting in a H₂-air front, which moves through the anode flow field. When the fuel cell is shut-down, a H₂/air front forms by the gas switching moves through the anode flow field in the reverse direction. It is known that hydrogen and oxygen within the moving H₂/air front can recombine and produce water, especially when catalyst such as platinum is present. This reaction can be relatively violent.

### SUMMARY

In one aspect, the present disclosure describes an article comprising:
a catalyst comprising Pt, the catalyst having surface area;
an oxygen evolution reaction catalyst on a portion of the surface area of the catalyst comprising Pt; and
and at least one of Au, a refractory metal (typically at least one of Hf, Nb, Os, Re, Rh, Ta, Ti, W, or Zr), a refractory metal oxide (including metal oxide (e.g., ZrO₂) doped with a metal oxide for crystal structure stabilization), a refractory metal boride, a refractory metal carbide, a refractory metal nitride, or a refractory metal silicide on a portion of the surface area of the catalyst comprising Pt, wherein a portion of the surface area of the catalyst comprising Pt is not covered by either the oxygen evolution reaction catalyst or collectively the Au refractory metal, refractory metal oxide, refractory metal boride, refractory metal carbide, refractory metal nitride, and refractory metal silicide to the extent present. In some embodiments, a portion of the oxygen evolution reaction catalyst is covered by the at least one of Au, a refractory metal, a refractory metal oxide, a refractory metal boride, a refractory metal carbide, a refractory metal nitride, or a refractory metal silicide. In some embodiments, a portion of the at least one of Au, a refractory metal, a refractory metal oxide, a refractory metal boride, a refractory metal carbide, a refractory metal nitride, or a refractory metal silicide is covered by a portion of the oxygen evolution reaction catalyst.

In another aspect, the present disclosure describes methods for making articles described herein.

Surprisingly, embodiments of the article discovered by Applicants typically exhibit improved OER catalyst effectiveness with repeated start-up/shut-down events over time as compared to the same article without the at least one of Au, a refractory metal, a refractory metal oxide, a refractory metal boride, a refractory metal carbide, a refractory metal nitride, or a refractory metal silicide.

Fuel cell anodes described herein are useful, for example, in fuel cells.

### BRIEF DESCRIPTION OF THE DRAWING

FIG. 1 is an exemplary fuel cell including a fuel cell anode described herein.

FIG. 2 is a plot of the results of the evaluation of Examples 1 and 2 and Comparative Example A using the MEA Evaluation Method I.

FIG. 3 is a plot of the results of the evaluation of the Examples 3 and 4 MEAs using the MEA Evaluation Method II.

FIG. 4 is a plot of the results of the evaluation of Examples 5 and 6 using the MEA Evaluation Method I.

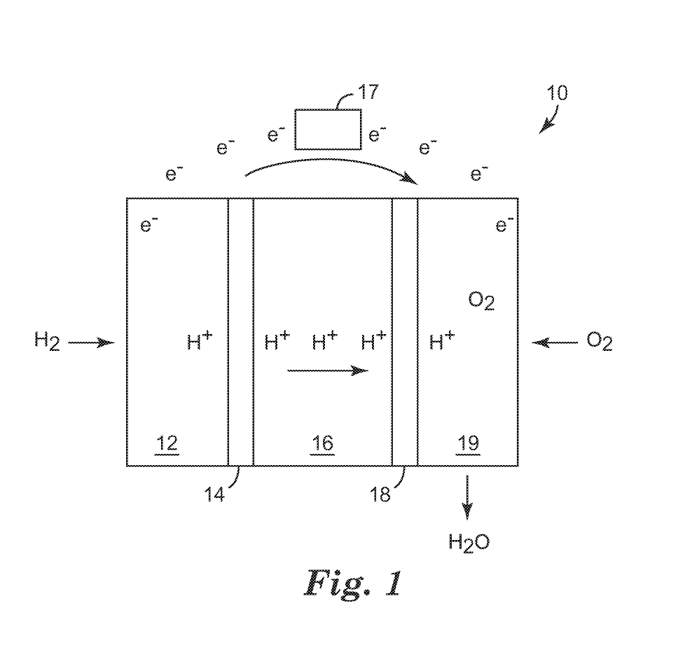

### DETAILED DESCRIPTION

Typically, articles described herein further comprise nanostructured whiskers with the catalyst comprising Pt thereon. Nanostructured whiskers can be provided by techniques known in the art, including those described in U.S. Pat. No. 4,812,352 (Debe), U.S. Pat. No. 5,039,561 (Debe), U.S. Pat. No. 5,338,430 (Parsonage et al.), U.S. Pat. No. 6,136,412 (Spiewak et al.), and U.S. Pat. No. 7,419,741 (Vernstrom et al.), the disclosures of which are incorporated herein by reference. In general, nanostructured whiskers can be provided, for example, by vacuum depositing (e.g., by sublimation) a layer of organic or inorganic onto substrate (e.g., a microstructured catalyst transfer polymer), and then converting the perylene red pigment into nanostructured whiskers by thermal annealing. Typically the vacuum deposition steps are carried out at total pressures at or below about 10⁻³ Torr or 0.1 Pascal. Exemplary microstructures are made by thermal sublimation and vacuum annealing of the organic pigment C.I. Pigment Red 149 (i.e., N,N′-di(3,5-xylyl)perylene-3,4:9,10-bis(dicarboximide)). Methods for making organic nanostructured layers are disclosed, for example, in Materials Science and Engineering, A158 (1992), pp. 1-6; J. Vac. Sci. Technol. A, 5 (4), July/August, 1987, pp. 1914-16; J. Vac. Sci. Technol. A, 6, (3), May/August, 1988, pp. 1907-11; Thin Solid Films, 186, 1990, pp. 327-47; J. Mat. Sci., 25, 1990, pp. 5257-68; Rapidly Quenched Metals, Proc. of the Fifth Int. Conf. on Rapidly Quenched Metals, Wurzburg, Germany (Sep. 3-7, 1984), S. Steeb et al., eds., Elsevier Science Publishers B.V., New York, (1985), pp. 1117-24; Photo. Sci. and Eng., 24, (4), July/August, 1980, pp. 211-16; and U.S. Pat. No. 4,340,276 (Maffitt et al.) and U.S. Pat. No. 4,568,598 (Bilkadi et al.), the disclosures of which are incorporated herein by reference. Properties of catalyst layers using carbon nanotube arrays are disclosed in the article “High Dispersion and Electrocatalytic Properties of Platinum on Well-Aligned Carbon Nanotube Arrays,” Carbon 42 (2004) 191-197. Properties of catalyst layers using grassy or bristled silicon are disclosed, for example, in U.S. Pat. App. Pub. 2004/0048466 A1 (Gore et al.).

Vacuum deposition may be carried out in any suitable apparatus (see, e.g., U.S. Pats. No. 5,338,430 (Parsonage et al.), U.S. Pat. No. 5,879,827 (Debe et al.), U.S. Pat. No. 5,879,828 (Debe et al.), U.S. Pat. No. 6,040,077 (Debe et al.), and U.S. Pat. No. 6,319,293 (Debe et al.), and U.S. Pat. App. Pub. No. 2002/0004453 A1 (Haugen et al.), the disclosures of which are incorporated herein by reference. One exemplary apparatus is depicted schematically in FIG. 4A of U.S. Pat. No. 5,338,430 (Parsonage et al.), and discussed in the accompanying text, wherein the substrate is mounted on a drum which is then rotated over a sublimation or evaporation source for depositing the organic precursor (e.g., perylene red pigment) to the nanostructured whiskers.

Typically, the nominal thickness of deposited perylene red pigment is in a range from about 50 nm to 500 nm. Typically, the whiskers have an average cross-sectional dimension in a range from 20 nm to 60 nm and an average length in a range from 0.3 micrometer to 3 micrometers.

In some embodiments, the whiskers are attached to a backing. Exemplary backings comprise polyimide, nylon, metal foils, or other material that can withstand the thermal annealing temperature up to 300° C. In some embodiments, the backing has an average thickness in a range from 25 micrometers to 125 micrometers.

In some embodiments, the backing has a microstructure on at least one of its surfaces. In some embodiments, the microstructure is comprised of substantially uniformly shaped and sized features at least three (in some embodiments, at least four, five, ten or more) times the average size of the nanostructured whiskers. The shapes of the microstructures can, for example, be V-shaped grooves and peaks (see, e.g., U.S. Pat. No. 6,136,412 (Spiewak et al.), the disclosure of which is incorporated herein by reference) or pyramids (see, e.g., U.S. Pat. No. 7,901,829 (Debe et al.), the disclosure of which is incorporated herein by reference). In some embodiments some fraction of the microstructure features extend above the average or majority of the microstructured peaks in a periodic fashion, such as every 31^{st} V-groove peak is 25% or 50% or even 100% taller than those on either side of it. In some embodiments, this fraction of features that extend above the majority of the microstructured peaks can be up to 10% (in some embodiments up to 3%, 2%, or even up to 1%). Use of the occasional taller microstructure features may facilitate protecting the uniformly smaller microstructure peaks when the coated substrate moves over the surfaces of rollers in a roll-to-roll coating operation. The occasional taller feature touches the surface of the roller rather than the peaks of the smaller microstructures and so much less of the nanostructured material or whiskers are likely to be scraped or otherwise disturbed as the substrate moves through the coating process. In some embodiments, the microstructure features are substantially smaller than half the thickness of the membrane that the catalyst will be transferred to in making a membrane electrode assembly (MEA). This is so that during the catalyst transfer process, the taller microstructure features do not penetrate through the membrane where they may overlap the electrode on the opposite side of the membrane. In some embodiments, the tallest microstructure features are less than ⅓^{rd} or ¼^{th} of the membrane thickness. For the thinnest ion exchange membranes (e.g., about 10 micrometers to 15 micrometers in thickness), it may be desirable to have a substrate with microstructured features no larger than about 3 micrometers to 4.5 micrometers tall. The steepness of the sides of the V-shaped or other microstructured features or the included angles between adjacent features may in some embodiments be desirable to be on the order of 90° for ease in catalyst transfer during a lamination-transfer process and have a gain in surface area of the electrode that comes from the square root of two (1.414) surface area of the microstructured layer relative to the planar geometric surface of the substrate backing.

Exemplary refractory metal can be selected from the group consisting of Hf, Nb, Os, Re, Rh, Ta, Ti, W, Zr, and combinations thereof. Exemplary refractory metal oxides, borides, carbides, nitrides and silicides in stoichiometric and nonpstoichiometric forms can be selected from the groups consisting of oxides, borides, carbides, nitrides, silicides, and combinations there as applicable (e.g., oxycarbides, oxynitrides, oxyborides, carbonitrides, carboborides boronitrides, borosilicides, carbosilicides, and nitrosilicides). Further, two or more refractory metals can be combined into binary, ternary, quaternary, etc. mixtures (e.g., M—M₂—O—B—C—N—Si, where M is a refractory metal(s).

Exemplary Hf oxides and suboxides include HfO, Hf₂O₃, and HfO₂. Exemplary Hf borides include HfB and HfB₂. Exemplary Hf carbides include HfC and HfC₂. Exemplary Hf nitrides include Hf₃N₄ and HfN. Exemplary Hf silicides include HfSi and HfSi₂.

Exemplary Nb oxides include NbO, NbO₂, and Nb₂O₅. Exemplary Nb borides include Nb₂B, Nb₃B₂, NbB, Nb₃B₄, Nb₅B₆, and NbB₂. Exemplary Nb carbides include Nb₂C and NbC. Exemplary Nb nitrides include Nb₂N, NbN, and Nb carbonitride. Exemplary Nb silicides include Nb₅Si₃.

Exemplary Os oxides include OsO₂ and OsO₄. Exemplary Os borides include OsB and OsB₂. Exemplary Os carbides include OsC, OsC₃, and OsC₂. Exemplary Os nitrides include OsN, OsN₂, and OsN₄. Exemplary Os silicides include Os₂Si₃, OsSi, and OsSi₂.

Exemplary Re oxides include ReO₂, ReO₃, Re₂O₃, and Re₂O₇. Exemplary Re borides include Re₃B, Re₇B₃, Re₂B, ReB, Re₂B₃, Re₃B₇, Re₂B₅, and ReB₃. Exemplary Re carbides include Re₂C. Exemplary Re nitrides include Re₂N, Re₃N, and ReN. Exemplary Re silicides include ReSi and ReSi₂.

Exemplary Rh oxides include RhO, RhO₂, and Rh₂O₃. Exemplary Rh borides include ZrRh₃B,

NbRh₃B, and RhB. Exemplary Rh carbides include RhC, Rh₂C, Rh₃C and Rh₄C. Exemplary Rh nitrides include RhN, RhN₂, and RhN₃. Exemplary Rh silicides include CeRhSi₂ and Ce₂Rh₃Si₅.

Exemplary Ta oxides include TaO and Ta₂O₅. Exemplary Ta borides include Ta₂B, Ta₃B₂, TaB, Ta₅B₆, Ta₃B₄, and TaB₂. Exemplary Ta carbides include TaC, Ta₄C₃, and Ta₂C. Exemplary Ta nitrides include TaN, Ta₂N, Ta₅N₆, and Ta₃N₅. Exemplary Ta silicides include TaSi₂, Ta₅Si₃, and Ta5Si6.

Exemplary W oxides include W₂O₃ and WO₃. Exemplary W borides include W₂B, WB, WB₂, W₂B₅, and WB₄. Exemplary W carbides include WC and WC₂. Exemplary W nitrides include W₂N, WN, and WN₂. Exemplary W silicides include WSi₂ and W₅Si₃.

Exemplary Zr oxides include ZrO, Zr₂O₃, and ZrO₂. Exemplary Zr oxides or zirconia, which are doped with the metal oxides acting as stabilizers for its crystal structure include yttria-, calcia-, magnesia-, alumina- and ceria-stabilized zirconia or zirconia-hafnia. Exemplary Zr borides include ZrB₂. Exemplary Zr carbides include Zr₂C, Zr₃C₂, and Zr₆C₅. Exemplary Zr nitrides include Zr₃N₄ and ZrN. Exemplary Zr silicides include Zr₂Si, Zr₃Si₂, ZrSi₂, Zr₅Si₃, and ZrSi.

Exemplary organometallic complexes comprising at least one of Ir, Pd, or Ru, include complexes where Ir, Pd, and Ru in valence states I-VIII form coordination bonds with organic ligands through hetero-atom(s) or non-carbon atom(s) such as oxygen, nitrogen, chalcogens (e.g., sulfur and selenium), phosphorus, or halide. Exemplary Ir, Pd, and Ru complexes with organic ligands can also be formed via π bonds. Organic ligands with oxygen hetero-atom include functional groups such as hydroxyl, ether, carbonyl, ester, carboxyl, aldehydes, anhydrides, cyclic anhydrides, and epoxy. Organic ligand with nitrogen hetero atom include functional groups such as amine, amide, imide, imine, azide, azine, pyrrole, pyridine, porphyrine, isocyanate, carbamate, carbamide sulfamate, sulfamide, amino acids, and N-heterocyclic carbine. Organic ligands with sulfur hetero atom, so-called thio-ligands include functional groups such as thiol, thioketone (thione or thiocarbonyl), thial, thiophene, disulfides, polysulfides, sulfimide, sulfoximide, and sulfonediimine. Organic ligands with phosphorus hetero-atom include functional groups such as phosphine, phosphane, phosphanido, and phosphinidene. Exemplary organometallic complexes also include homo and hetero bimetallic complexes where Ir, Pd, and/or Ru are involved in coordination bonds with either homo or hetero functional organic ligands. Ir, Pd, and/or Ru organometallic complexes formed via π coordination bonds include carbon rich π-conjugated organic ligands such as arenes, allyls, dienes, carbenes, and alkynyls. Examples of Ir, Pd, and Ru organometallic complexes are also known as chelates, tweezer molecules, cages, molecular boxes, fluxional molecules, macrocycles, prism, half-sandwich, and metal-organic framework (MOF).

Exemplary organometallic compounds comprising at least one of Ir, Pd, or Ru include compounds where Ir, Pd, and/or Ru bond to organics via covalent, ionic or mixed covalent-ionic metal-carbon bonds. Exemplary organometallic compounds can also include combination of at least two of Ir, Pd, or Ru covalent bonds to carbon atoms and coordination bond to organic ligands via hetero-atoms.

Metallic Ir refers to Ir metals, Ir alloys, and Ir composites in an amorphous state, crystalline state or combination thereof.

Exemplary Ir compounds include Ir oxides, Ir hydrated oxides (i.e., hydrated Ir oxides), Ir polyoxometallate, Ir heteropolyacids, metal iridates, Ir nitrides, Ir oxonitrides, Ir carbides, Ir tellurides, Ir antimonides, Ir selenides, Ir borides, Ir sillicides, Ir arsenides, Ir phosphides, and Ir halides.

Exemplary Ir oxides include IrₓO_{y} forms where Ir valence could be, for example, 2-8. Specific exemplary Ir oxides include Ir₂O₃, IrO₂, IrO₃, and IrO₄, as well as IrₓRu_{y}O_{z}, IrₓPt_{y}O_{z}, IrₓRu_{y}Pt_{z}O_{zz}, IrₓPd_{y}Pt_{z}O_{zz}, IrₓPd_{y}O_{z}, and IrₓRu_{y}Pd_{z}O_{zz}.

Metallic Pd refers to Pd metals, Pd alloys, and Pd composites in an amorphous state, crystalline state or combination thereof.

Exemplary Pd alloys include bi-, tri,-and multi-metallic.

Exemplary Pd compounds include Pd oxides, Pd hydrated oxides (i.e., hydrated Pd oxides), Pd polyoxometallate, Pd heteropolyacids, metal paladates, Pd nitrides, Pd oxonitrides, Pd carbides, Pd tellurides, Pd antimonides, Pd selenides, Pd borides, Pd sillicides, Pd arsenides, Pd phosphides, and Pd halides.

Exemplary Pd oxides include PdₓO_{y} forms where Pd valence could be, for example, 1, 2, and 4. Specific exemplary Pd oxides include PdO, PdO₂, IrₓPd_{y}Pt_{z}O_{zz}, IrₓPd_{y}O_{z}, IrₓRu_{y}Pd_{z}O_{zz}, RuₓPd_{y}Pt_{z}O_{zz}, RuₓPd_{y}O_{z}, and RuₓIr_{y}Pt_{z}Pd_{yy}O_{zz}.

Metallic Pt refers to Pt metals, Pt alloys, and Pt composites in an amorphous state, crystalline state or combination thereof.

Exemplary Pt compounds include Pt oxides, Pt hydrated oxides, Pt hydroxides, Pt polyoxometallate, Pt heteropolyacids, metal platinates, Pt nitrides, Pt oxonitrides, Pt carbides, Pt tellurides, Pt antimonides, Pt selenides, Pt borides, Pt sillicides, Pt arsenides, Pt phosphides, Pt halides, Pt organometallic complexes, and chelates, as well as bi and multi metallic Pt compounds.

Exemplary Pt alloys include bi-, tri-, and multi-metallic Pt—Ir, Pt—Ru, Pt—Sn, Pt—Co, Pt—Pd, Pt—Au, Pt—Ag, Pt—Ni, Pt—Ti, Pt—Sb, Pt—In, Pt—Ga, Pt—W, Pt—Rh, Pt—Hf, Pt—Cu, Pt—Al, Pt—Fe, Pt—Cr, Pt—Mo, Pt—Mn, Pt—Zn, Pt—Mg, Pt—Os, Pt—Ge, Pt—As, Pt—Re, Pt—Ba, Pt—Rb, Pt—Sr, and Pt—Ce.

Metallic Ru means Ru metals, Ru alloys, and Ru composites in an amorphous state, crystalline state, or combination thereof.

Exemplary Ru compounds include Ru oxides, Ru hydrated oxides (i.e., hydrated Ru oxides), Ru polyoxometallate, Ru heteropolyacids, metal ruthenates, Ru nitrides, Ru oxonitrides, Ru carbides, Ru tellurides, Ru antimonides, Ru selenides, Ru borides, Ru silicides, Ru arsenides, Ru phosphides, and Ru halides.

Exemplary Ru oxides include Ruₓ₁O_{y1}, where valence could be, for example, 2-8. Specific exemplary Ru oxides include Ru₂O₃, RuO₂, and RuO₃, as well as RuIrOx, RuPtOₓ, RuIrPtOₓ, RuₓPd_{y}Pt_{z}O_{zz}, RuₓPd_{y}O_{z}, and RuₓIr_{y}Pt_{z}Pd_{yy}O_{zz}.

In general, the catalyst comprising Pt and the oxygen evolution reaction catalyst can be deposited by techniques known in the art. Exemplary deposition techniques include those independently selected from the group consisting of sputtering (including reactive sputtering), atomic layer deposition, molecular organic chemical vapor deposition, molecular beam epitaxy, ion soft landing, thermal physical vapor deposition, vacuum deposition by electrospray ionization, and pulse laser deposition. Additional general details can be found, for example, in U.S. Pat. No. 5,879,827 (Debe et al.), U.S. Pat. No. 6,040,077 (Debe et al.), and. U.S. Pat. No. 7,419,741 (Vernstrom et al.), the disclosures of which are incorporated herein by reference).

Materials comprising the multiple alternating layers can be sputtered, for example, from a multiple targets (e.g., Ir is sputtered from a first target, Pt is sputtered from a second target, Ru from a third (if present), etc.), or from a target(s) comprising more than one element.

In some embodiments, catalyst is coated in-line, in a vacuum immediately following the nanostructured whisker growth step on the microstructured substrate. This may be a more cost effective process so that the nanostructured whisker coated substrate does not need to be re-inserted into the vacuum for catalyst coating at another time or place. If the catalyst alloy coating is done with a single target, it may be desirable that the coating layer be applied in a single step onto the nanostructured whisker so that the heat of condensation of the catalyst coating heats the Au, Ir, Pd, Pt, Ru, refractory metal, etc. atoms as applicable and substrate surface sufficient to provide enough surface mobility that the atoms are well mixed and form thermodynamically stable alloy domains. Alternatively the substrate can also be provided hot or heated to facilitate this atomic mobility, such as by having the nanostructured whisker coated substrate exit the perylene red annealing oven immediately prior to the catalyst sputter deposition step.

Ruthenium, palladium, and/or iridium organometallics can be deposited, for example, by soft or reactive landing of mass selected ions. Soft landing of mass-selected ions is used to transfer catalytically-active metal complexes complete with organic ligands from the gas phase onto an inert surface. This method can be used to prepare materials with defined active sites and thus achieve molecular design of surfaces in a highly controlled way under either ambient or traditional vacuum conditions. For additional details see, for example, G. E. Johnson, M. Lysonsky, and J. Laskin, Anal. Chem 2010, 82, 5718-5727, and G. E. Johnson and J. Laskin, Chemistry: A European Journal 16, 14433-14438.

Ruthenium, palladium, and iridium organometallics can be deposited, for example, by thermal physical vapor deposition. This method uses high temperature (e.g., via resistive heating, electron beam gun, or laser) to melt or sublimate the target (source material) into vapor state which is in turn passed through a vacuum space, then condensing of the vaporized form to substrate surfaces. Thermal physical vapor deposition equipment is known in the art, including that available, for example, as an organic molecular evaporator from CreaPhys GmbH, Dresden, Germany.

In some embodiments, the oxygen evolution reaction catalyst is deposited first, followed by the at least one of Au, a refractory metal, a refractory metal oxide, a refractory metal boride, a refractory metal carbide, a refractory metal nitride, or a refractory metal silicide. Therefore, in some embodiments, a portion of the oxygen evolution reaction catalyst is covered by the at least one of Au, a refractory metal, a refractory metal oxide, a refractory metal boride, a refractory metal carbide, a refractory metal nitride, or a refractory metal silicide.

In some embodiments, the at least one of Au, a refractory metal, a refractory metal oxide, a refractory metal boride, a refractory metal carbide, a refractory metal nitride, or a refractory metal silicide is deposited first followed by the oxygen evolution reaction catalyst (e.g., ZrO₂ on a portion of the Au). Therefore, in some embodiments, a portion of the at least one of Au, a refractory metal, a refractory metal oxide, a refractory metal boride, a refractory metal carbide, a refractory metal nitride, or a refractory metal silicide is covered by a portion of the oxygen evolution reaction catalyst.

In some embodiments, the deposition of the catalyst comprising Pt, the oxygen evolution reaction catalyst, and the at least one of Au, a refractory metal, a refractory metal oxide, a refractory metal boride, a refractory metal carbide, a refractory metal nitride, or a refractory metal silicide are conducted under the same vacuum (i.e., the vacuum is not broken between any of the respective depositions). In some embodiments, the nanostructured whisker growth is also conducted under the same vacuum.

In some embodiments, at least one of the layers is annealed (e.g., radiation annealed at least in part). In some embodiments, the radiation annealing is conducted at an incident energy fluence of at least 20 mJ/mm², for example, with a 10.6 micrometer wavelength CO₂ laser having an average beam power of 30.7 watts and average beam width of 1 mm, that is delivered in the form of 30 microsecond pulses at a repetition rate of 20 kHz while scanning over the surface at about 7.5 m/sec in five sequential passes, each displaced 0.25 mm from the previous pass.

In some embodiments, the radiation annealing is conducted at least in part in an atmosphere comprising an absolute oxygen partial pressure of at least 2 kPa (in some embodiments, at least 5 kPa, 10 kPa, 15 kPa, or even at least 20 kPa) oxygen. The radiation annealing (e.g., laser annealing) is useful for rapidly heating the catalyst coating on the whiskers to effectively heat the catalyst coating so that there is sufficient atomic mobility that the alternately deposited layers are further intermixed to form more extensive alloying of the materials and larger crystalline grain sizes. It may be desirable for the radiation annealing to be able to be applied at sufficiently rapid web speeds that the process can match the original manufacturing process speeds of the nanostructured catalyst. For example it may be useful if the radiation annealing is conducted in line with the deposition process of the catalyst coating. It may be further be desirable if the radiation annealing is conducted in-line, in the vacuum, immediately follow the catalyst deposition.

It will be understood by one skilled in the art that the crystalline and morphological structure of a catalyst described herein, including the presence, absence, or size of alloys, amorphous zones, crystalline zones of one or a variety of structural types, and the like, may be highly dependent upon process and manufacturing conditions, particularly when three or more elements are combined.

In some embodiments, the first layer is directly on the nanostructured whiskers. In some embodiments, the first layer is at least one of covalently or ionically bonded to the nanostructured whiskers. In some embodiments, the first layer is adsorbed onto the nanostructured whisker. The first layer can be formed, for example as a uniform conformal coating or as dispersed discrete nanoparticles. Dispersed discrete tailored nanoparticles can be formed, for example, by a cluster beam deposition method by regulating the pressure of helium carrier gas or by self-organization. For additional details see, for example, Wan et al., Solid State Communications, 121, 2002, 251-256 or Bruno Chaudret, Top Organomet Chem, 2005, 16, 233-259.

In some embodiments, the Pt is present in a range from 0.5 microgram/cm² to 100 micrograms/cm² (in some embodiments, in a range from 1 microgram/cm² to 100 micrograms 0.5 microgram/cm² to 50 micrograms, 1 microgram/cm² to 50 micrograms, or even 10 micrograms/cm² to 50 micrograms/cm²).

In some embodiments, the oxygen evolution reaction catalyst is present in a range from 0.5 microgram/cm² to 250 micrograms/cm² (in some embodiments, in a range from 1 microgram/cm² to 250 micrograms/cm², 1 microgram/cm² to 200 micrograms/cm², 1 microgram/cm² to 150 micrograms/cm², 1 microgram/cm² to 100 micrograms/cm², 1 microgram/cm² to 50 micrograms/cm², 1 microgram/cm² to 250 micrograms/cm², 5 micrograms/cm² to 200 micrograms/cm², 5 micrograms/cm² to 150 micrograms/cm², 5 micrograms/cm² to 100 micrograms/cm², 5 micrograms/cm² to 50 micrograms/cm², 10 micrograms/cm² to 200 micrograms/cm², 10 micrograms/cm² to 150 micrograms/cm², 10 micrograms/cm² to 100 micrograms/cm², or even 10 micrograms/cm² to 50 micrograms/cm²).

In some embodiments, the Au, refractory metal, refractory metal oxide, refractory metal carbide, refractory metal carbide, refractory metal nitride, and refractory metal silicide, to the extent, present, is collectively present in a range from 0.5 microgram/cm² to 100 micrograms/cm² (in some embodiments, in a range from 1 microgram/cm² to 100 micrograms/cm², 1 microgram/cm² to 75 micrograms/cm², 1 microgram/cm² to 50 micrograms/cm², 5 micrograms/cm² to 75 micrograms/cm², 5 micrograms/cm² to 50 micrograms/cm², 10 micrograms/cm² to 50 micrograms/cm², or even 10 micrograms/cm² to 40 micrograms/cm²).

In some embodiments, the oxygen evolution reaction catalyst and the Au , refractory metal, refractory metal oxide, refractory metal carbide, refractory metal carbide, refractory metal nitride, and refractory metal silicide, to the extent present, collectively cover in a range from 2 percent to not greater than 95 percent of the surface area of the catalyst comprising Pt (in some embodiments, in a range from 10 percent to 95 percent, 25 percent to 95 percent, 10 percent to 90 percent, 25 percent to 90 percent, 50 percent to 90 percent, or even 50 percent to 80 percent).

Fuel cell anodes described herein are useful in fuel cells. Referring to the FIG., fuel cell 10 includes first gas diffusion layer (GDL) 12 adjacent anode described herein 14. Adjacent anode 14 includes electrolyte membrane 16. Cathode 18 is adjacent electrolyte membrane 16, and second gas diffusion layer 19 is adjacent the cathode 18. GDLs 12 and 19 can be referred to as diffuse current collectors (DCCs) or fluid transport layers (FTLs). In operation, hydrogen fuel is introduced into the anode portion of fuel cell 10, passing through first gas diffusion layer 12 and over anode 14. At anode 14, the hydrogen fuel is separated into hydrogen ions (^{H+}) and electrons (^{e-}).

Electrolyte membrane 16 permits only the hydrogen ions or protons to pass through electrolyte membrane 16 to the cathode portion of fuel cell 10. The electrons cannot pass through electrolyte membrane 16 and, instead, flow through an external electrical circuit in the form of electric current. This current can power, for example, electric load 17, such as an electric motor, or be directed to an energy storage device, such as a rechargeable battery.

Oxygen flows into the cathode side of fuel cell 10 via second gas diffusion layer 19. As the oxygen passes over cathode 18, oxygen, protons, and electrons combine to produce water and heat. In some embodiments, the fuel cell catalyst comprises no electrically conductive carbon-based material (i.e., perylene red, fluoropolymers, or polyolefines).

At the start up of a fuel cell the anode compartment is usually under air. The incoming hydrogen contacts the air, the consequences of which can be detrimental for the stability of both the anode and the cathode catalyst. As reported to Applicants by a third party, prior to discovering the at least one of Au, a refractory metal, a refractory metal oxide, a refractory metal boride, a refractory metal carbide, a refractory metal nitride, or a refractory metal silicide, this effect is believed to be especially damaging to the OER catalyst deposited to the PT/NSTF anode. The OER catalyst on the anode serves as protection for the so called cell reversal, a situation when the anode is deprived of hydrogen and under the voltage imposed on the cell by the rest of the fuel cells in the stack, the anode gets more positive than the cathode (hence the term “cell reversal”). Although not wanting to be bound by theory, the purpose of the catalyst in this case is to keep the anode voltage as low as possible by electrolyzing water (i.e., by promoting the oxygen evolution reaction (OER)). The OER catalyst is usually composed either of Ir(100% at.) or Ir(90% at.)Ru(10% at.). The performance of the OER catalyst can be expressed by the time the OER catalyst as being capable to hold the voltage below a certain level at a given current. Before the simulated SU/SD by gas switching, a typical loading of 15 micrograms/cm² OER catalyst was able to achieve over 26,000 s at current density of 0.2 A/cm² before the voltage reaches 2.2 V (vs. hydrogen flowing on the opposite electrode). After 400 of the simulated SU/SD by gas switching, this value dropped to less than 2,000 seconds. The reason for the loss of the OER effectiveness due to the gas switching is unknown. High voltage can be excluded because during SU/SD the anode does not see voltage above 1.1V. Hence, although not wanting to be bound by theory, that leaves the heat as the major contributor. What is known is that hydrogen and oxygen can recombine and produce water when a catalyst such as platinum is present. This reaction can be relatively violent. Heat is evolved on the platinum on which the OER catalyst resides. Therefore, the heat can impact the IrRu instantly, before it gets a chance to dissipate the heat. Although not wanting to be bound by theory, it is believed the heat can alter IrRu activity, although the mechanism (e.g., non-stoichiometric oxide formation, different than the usual electrochemically formed thin oxide) is not known. Scanning Transmission Electron Microscopy (STEM) confirmed that Ir was still be present on the Pt, yet has greatly reduced activity as determined by fuel cell testing. Although not wanting to be bound by theory, it is believed having the at least one of Au, a refractory metal, a refractory metal oxide, a refractory metal boride, a refractory metal carbide, a refractory metal nitride, or a refractory metal silicide covering a portion of the catalyst (e.g., Pt), yet leaving enough free sites for the HOR to proceed uninhibited improves the effectiveness of the OER catalyst with repeated start-up/shut-down events over time as compared to the same article without the at least one of Au, a refractory metal, a refractory metal oxide, a refractory metal boride, a refractory metal carbide, a refractory metal nitride, or a refractory metal silicide.

### Exemplary Embodiments

1. A fuel cell anode comprising:
a catalyst comprising Pt, the catalyst having surface area;
an oxygen evolution reaction catalyst on a portion of the surface area of the catalyst comprising Pt; and
and at least one of Au, a refractory metal (typically at least one of Hf, Nb, Os, Re, Rh, Ta, Ti, W, or Zr), a refractory metal oxide, a refractory metal boride, a refractory metal carbide, a refractory metal nitride, or a refractory metal silicide on a portion of the surface area of the catalyst comprising Pt, wherein a portion of the surface area of the catalyst comprising Pt is not covered by either the oxygen evolution reaction catalyst or collectively the Au, the refractory metal, refractory metal oxide, refractory metal boride, refractory metal carbide, refractory metal nitride, and refractory metal silicide to the extent present.

2. The fuel cell anode of Embodiment 1, wherein the refractory is one of a refractory metal, a refractory metal oxide, a refractory metal boride, a refractory metal carbide, a refractory metal nitride, or a refractory metal silicide is independently selected from the group consisting of Hf, Nb, Os, Re, Rh, Ta, Ti, W, Zr, and combinations thereof.

3. The fuel cell anode of any preceding Embodiment, wherein Pt present in the catalyst comprising Pt is present as at least one of metallic Pt or Pt compound.

4. The fuel cell of either Embodiment 1 or 2, wherein the catalyst comprising Pt further comprises at least one of Ir, Ru, or Pd.

5. The fuel cell of any preceding Embodiment, wherein at least some of the least one of Ir, Ru, or Pd is present in at least one organometallic compound.

6. The fuel cell of Embodiment 5, wherein at one organometallic compound present is one of an oxide or a hydrated oxide.

7. The fuel cell of any preceding Embodiment, wherein at least some of the least one of Ir, Ru, or Pd is present in at least one organometallic complex.

8. The fuel cell anode of any preceding Embodiment, wherein the Pt is present in a range from 0.5 microgram/cm² to 100 micrograms/cm² (in some embodiments, in a range from 1 microgram/cm² to 100 micrograms 0.5 microgram/cm² to 50 micrograms, 1 microgram/cm² to 50 micrograms, or even 10 micrograms/cm² to 50 micrograms/cm²).

9. The fuel cell of any preceding Embodiment, wherein the oxygen evolution reaction catalyst is present in a range from 0.5 microgram/cm² to 250 micrograms/cm² (in some embodiments, in a range from 1 microgram/cm² to 250 micrograms/cm², 1 microgram/cm² to 200 micrograms/cm², 1 microgram/cm² to 150 micrograms/cm², 1 microgram/cm² to 100 micrograms/cm², 1 microgram/cm² to 50 micrograms/cm², 1 microgram/cm² to 250 micrograms/cm², 5 micrograms/cm² to 200 micrograms/cm², 5 micrograms/cm² to 150 micrograms/cm², 5 micrograms/cm² to 100 micrograms/cm², 5 micrograms/cm² to 50 micrograms/cm², 10 micrograms/cm² to 200 micrograms/cm², 10 micrograms/cm² to 150 micrograms/cm², 10 micrograms/cm² to 100 micrograms/cm², or even 10 micrograms/cm² to 50 micrograms/cm²).

10. The fuel cell of any preceding Embodiment, wherein the one Au, refractory metal, refractory metal oxide, refractory metal carbide, refractory metal carbide, refractory metal nitride, and refractory metal silicide, to the extent present, is collectively present in a range from 0.5 microgram/cm² to 100 micrograms/cm² (in some embodiments, in a range from 1 microgram/cm² to 100 micrograms/cm², 1 microgram/cm² to 75 micrograms/cm², 1 microgram/cm² to 50 micrograms/cm², 5 micrograms/cm² to 75 micrograms/cm², 5 micrograms/cm² to 50 micrograms/cm², 10 micrograms/cm² to 50 micrograms/cm², or even 10 micrograms/cm² to 40 micrograms/cm²).

11. The fuel cell of any preceding Embodiment, wherein the oxygen evolution reaction catalyst and the Au, refractory metal, refractory metal oxide, refractory metal carbide, refractory metal carbide, refractory metal nitride, and refractory metal silicide, to the extent present, collectively cover in a range from 2 percent to not greater than 95 percent of the surface area of the catalyst comprising Pt (in some embodiments, in a range from 10 percent to 95 percent, 25 percent to 95 percent, 10 percent to 90 percent, 25 percent to 90 percent, 50 percent to 90 percent, or even 50 percent to 80 percent).

12. The fuel cell of any preceding Embodiment further comprising nanostructured whiskers with the catalyst comprising Pt thereon.

13. The fuel cell of any preceding Embodiment, wherein the nanostructured whiskers are attached to a backing.

14. The fuel cell of Embodiment 13, wherein the backing has a microstructure on at least one of its surfaces.

15. The fuel cell catalyst of any preceding Embodiment which comprises no electrically conductive carbon-based material.

16. The fuel cell of any preceding Embodiment, wherein a portion of the oxygen evolution reaction catalyst is covered by the at least one of Au, a refractory metal, a refractory metal oxide, a refractory metal boride, a refractory metal carbide, a refractory metal nitride, or a refractory metal silicide.

17. The fuel cell of any of Embodiments 1 to 15, wherein a portion of the at least one of Au, a refractory metal, a refractory metal oxide, a refractory metal boride, a refractory metal carbide, a refractory metal nitride, or a refractory metal silicide is covered by a portion of the oxygen evolution reaction catalyst.

18. A method of making the fuel cell anode of the fuel cell of any preceding Embodiment, the method comprising depositing the catalyst comprising Pt via a deposition technique selected from the group consisting of sputtering, atomic layer deposition, molecular organic chemical vapor deposition, molecular beam epitaxy, ion soft landing, thermal physical vapor deposition, vacuum deposition by electrospray ionization, and pulse laser deposition.

19. A method of making the fuel cell anode of the fuel cell of any of Embodiments 1 to 17, the method comprising depositing the oxygen evolution reaction catalyst via a deposition technique independently selected from the group consisting of sputtering, atomic layer deposition, molecular organic chemical vapor deposition, molecular beam epitaxy, ion soft landing, thermal physical vapor deposition, vacuum deposition by electrospray ionization, and pulse laser deposition.

20. A method of making the fuel cell anode of the fuel cell of Embodiments 1 to 17, the method comprising:
depositing the catalyst comprising Pt via a deposition technique selected from the group consisting of sputtering, atomic layer deposition, molecular organic chemical vapor deposition, molecular beam epitaxy, ion soft landing, thermal physical vapor deposition, vacuum deposition by electrospray ionization, and pulse laser deposition; and
depositing the oxygen evolution reaction catalyst via a deposition technique independently selected from the group consisting of sputtering, atomic layer deposition, molecular organic chemical vapor deposition, molecular beam epitaxy, ion soft landing, thermal physical vapor deposition, vacuum deposition by electrospray ionization, and pulse laser deposition.

21. The method of making the fuel cell anode of the fuel cell of Embodiment 20, depositing the catalyst comprising Pt, the oxygen evolution reaction catalyst, and the at least one of Au, a refractory metal, a refractory metal oxide, a refractory metal boride, a refractory metal carbide, a refractory metal nitride, or a refractory metal silicide are conducted under the same vacuum.

Advantages and embodiments of this invention are further illustrated by the following examples, but the particular materials and amounts thereof recited in these examples, as well as other conditions and details, should not be construed to unduly limit this invention. All parts and percentages are by weight unless otherwise indicated.

### MEA Preparation

All the MEA's for the examples were made with the same perfluorinated sulfonic acid membrane (available from 3M Company, St. Paul, Minn.) with a nominal equivalent weight of 825. The membranes had a thickness of about 24 micrometers. The cathode catalyst layers were prepared from dispersed Pt catalyst (at a loading of 0.4 mg/cm² loading) by using methods well known in the art. The gas diffusion layers (GDL) were fabricated by coating a gas diffusion micro-layer on one side of a carbon paper electrode backing layer (obtained from Mitsubishi Rayon Corp., Tokyo, Japan) that had been treated with polytetrafluoroethylene (marketed under the trade designation “TEFLON” by E.I. du Pont de Nemours, Wilmington, Del.) to improve its hydrophobicity.

When the anode catalysts described in the Examples and Comparative Examples below were prepared, the corresponding 5-layer MEA's were prepared by using methods well known in the art.

### MEA Evaluation Method I

Example 1 and 2 and the Comparative Example described below were installed in 50 cm² cells, having quad-serpentine flow fields, at about 10% compression, and operated under a scripted protocol for break in and fuel cell performance testing. The test stations were obtained from Fuel Cell Technology, Albuquerque, NM. For this test method, the oxygen evolution reaction (OER) catalyst was operated as the cathode and a series of about 14 thermal cycles were performed to break in the OER catalyst and the MEA's. The cell had set points of 75° C. cell temperature, an anode flow of 800 sccm (standard cubic centimeters per minute) hydrogen at an inlet dew point of 68° C., cathode flow of 1800 sccm air at an inlet dew point of 68° C., with outlets being at ambient pressure. During the thermal cycle the MEA under test was exercised by doing three potentiodynamic scans between 0.9-0.3 volt. The “thermal cycles” were found helpful to sweep away impurities and bring up the performance of the thin film electrodes quickly.

Then the OER effectiveness durability of the anode catalysts was evaluated. The OER effectiveness durability was expressed as the time the OER catalyst was capable to hold the voltage below a predetermined level at a given current. The OER effectiveness durability was evaluated under nitrogen which was humidified to fill saturation at 70° C.

Gas switching was achieved by alternating the reactant anode (OER catalyst) from hydrogen to air (wherein oxygen was the reactant) by means of two different dedicated mass flow controllers while all other test station parameters were held fixed: the cell temperature 68° C., cathode air flow 1800 sccm air, inlet RH 70%, and outlet pressure 138 kPa gauge. This was in contrast to normal fuel cell use where the anode reactant gas is hydrogen. The degree of damage done to the anode and/or the cathode during start up / shut down (SU/SD) was a function of the number of transitions from one anode gas to the other. As the anode gas changed from hydrogen to air (oxygen) the voltage across the cell went from about 0.9 volt to 0 volt. The gas flow was alternated from 280 sccm air for 20 seconds to 800 sccm hydrogen for 15 seconds, and back again. In this particular test, this sequence was repeated until the desired number of gas switching events was obtained, herein referred to as a gas cycle. In the examples tested under Method I, the gas switching number was 400.

### MEA Evaluation Method II

Example 3 and 4 MEA's, prepared as described below, were installed in 50 cm² cells, and operated under a scripted protocol and broke in as would be done in a fuel cell stack. The break in period consisted of about three hours operation at 60° C. cell temperature, anode flow of 2 (slpm) at an inlet dew point of 60° C., an outlet pressure of 172 kPa gauge, cathode flow of 4 slpm at an inlet dew point of 60° C. with an outlet pressure of 152 kPa gauge, and galvanostatic scanning at 1.5 Amp/cm². After this, the MEA's for Examples 3 and 4 were tested for reversal OER testing. The reversal OER test was done at 60° C. cell temperature, cathode flow of 1800 sccm air at an inlet dew point of 60° C. with outlet ambient pressure. There was no anode gas flow but water was pumped into the anode at a flow rate of 0.12 cm³/min. A current was forced across the cell, as would happen if one cell in a stack became hydrogen starved. In this case the current was 0.2 A/cm² for 10 hours or until the cell reached negative 1.5 volt. The results (i.e., reversal voltage versus time) were then plotted.

### Example 1

Preparation of Nanostructured Whiskers

Nanostructured whiskers were prepared by thermal annealing a layer of perylene red pigment (C.I. Pigment Red 149, also known as “PR149”, obtained from Clariant, Charlotte, NC), which was sublimation vacuum coated onto microstructured catalyst transfer polymer substrates (MCTS) with a nominal thickness of 200 nm), as described in detail in U.S. Pat. No. 4,812,352 (Debe), the disclosure of which is incorporated herein by reference.

### Preparation of Nanostructured Thin Film (NSTF) Catalyst Layers

Nanostructured thin film (NSTF) catalyst layers were prepared by sputter coating catalyst films of Pt, Ru, and Ir sequentially using a DC-magnetron sputtering process onto the layer of nanostructured whiskers. The relative thickness of each layer was varied as desired.

A vacuum sputter deposition system (obtained as Model Custom Research from Mill Lane Engineering Co., Lowell, Mass.) equipped with 4 cryo-pumps (obtained from Austin Scientific, Oxford Instruments, Austin, Tex.), a turbopump and using typical Ar sputter gas pressures of about 5 mTorr (0.66 Pa), and 2 inch×10 inch (5 cm×25.4 cm) rectangular sputter targets (obtained from Sophisticated Alloys, Inc., Butler, Pa.) was used. Before deposition, the sputtering chamber was evacuated to a base pressure of 7×10 ⁻⁷ Torr (9.3×10⁻⁶ Pa). The coatings were deposited by using ultra high purity Ar as the sputtering gas and magnetron power range from 30-300 Watts. High purity (99.99+%), Pt, Ir, and Ru were used for the sputtering targets. A pre-sputter of each target was performed to clean the surface before deposition. First, the Pt layer was coated directly on top of the nanostructured whiskers to obtain a Pt loading of about 0.05 mg/cm². Then, Ir(90% at.)-Ru (10% at.) catalyst over-layers were sputter-deposited onto the Pt layer to obtain an Ir-Ru catalyst loading of 15 micrograms/cm².

### Preparation of Au-Coated NSTF Catalyst

Finally, a layer of Au was coated onto NSTF catalyst prepared above by using an e-beam coater equipment (obtained as Model MK-50, from CHA Industries, Fremont, Calif.) to prepare the anode catalyst of Example 1. Three planetary rotators mounted with NSTF catalyst as a substrate rotated inside the system under vacuum with the 270 degree electron beam heating the Au source to its sublimation point. As the Au sublimated, the deposited amount of Au and the deposition rate were monitored in real time using a quartz crystal monitor (obtained under the trade designation “INFICON”; Model 6000, from CHA Industries, Fremont, Calif.). Once the Au deposit loading of 2 microgram/cm², on the NSTF catalyst was attained the power to the electron beam was terminated and the deposition ended. The system was then vented and the substrates removed.

The resulting Au-coated NSTF catalyst was used to as the anode catalyst layer to prepare Example 1 MEAs using MEA Evaluation Method I described above.

### Example 2 and Comparative Example

Example 2 was prepared in the same manner as Example 1, except that the Au deposited on the NSTF catalyst was at a loading of 4 microgram/cm². The resulting Au-coated NSTF catalyst was used to as the anode catalyst layer to prepare Example 2 MEAs using the method described above.

The Comparative Example was prepared in the same manner as Example 1 except that no Au was deposited on the NSTF catalyst. To prepare the MEA of the Comparative Example, the NSTF catalyst was used as the anode.

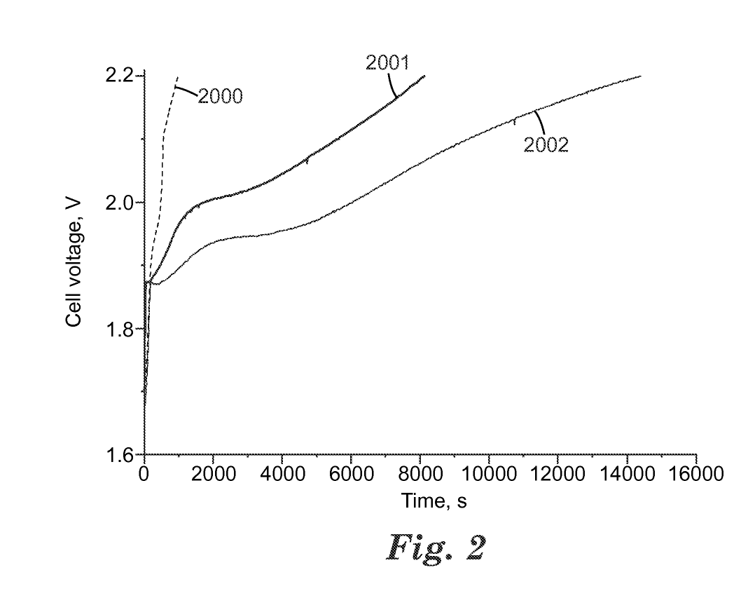

Example 1, Example 2, and Comparative Example MEA's were tested for their OER effectiveness durability using the MEA Evaluation Method I described above. The results are plotted in FIG. 2 for Examples 1 (2001) and 2 (2002) and the Comparative Example (2000).

### Examples 3 and 4

Examples 3 and 4 were prepared as described for Example 1, except that the NSTF catalyst used had a Pt loading of 50 microgram/cm² and Ir at a loading of 40 microgram/cm² with no Ru. The

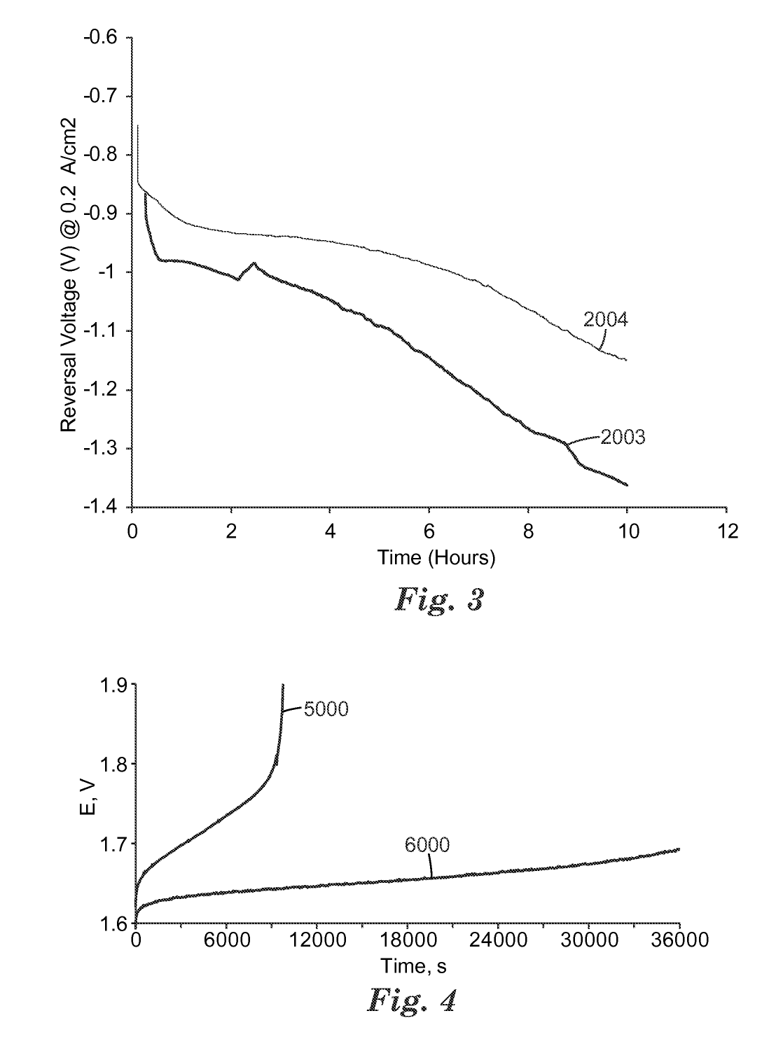

Examples 3 and 4 samples were then coated with Au at a loading of 8 micrograms/cm² and 24 micrograms/cm², respectively. Examples 3 and 4 MEA's were then tested using the MEA Evaluation Method II described above. The results are plotted in FIG. 3 for Examples 3 (2003) and 4 (2004).

### Example 5

Example 5 was prepared as described for Example 1, except that the NSTF catalyst used had a Pt loading of 0.02 mg/cm², followed by a Ir catalyst loading of 15 mg/cm², and then a Zr catalyst layer on top of Ir with a Zr catalyst loading of 16 mg/cm².

Example 5 was tested for its OER effectiveness durability using the MEA Evaluation Method I described above, except the number of gas switches was 200. The results are plotted in FIG. 4 (5000).

### Example 6

Example 6 was prepared as described for Example 1, except that the NSTF catalyst used had a Pt loading of 0.02 mg/cm², followed by a Zr catalyst loading of 16 mg/cm², and then a Ir layer on top of Zr catalyst with a Ir loading of 15 mg/cm².

Example 6 was tested for its OER effectiveness durability using the MEA Evaluation Method I described above, except the number of gas switches was 200. The results are plotted in FIG. 4 (6000).

Foreseeable modifications and alterations of this disclosure will be apparent to those skilled in the art without departing from the scope and spirit of this invention. This invention should not be restricted to the embodiments that are set forth in this application for illustrative purposes.

1. A hydrogen fuel cell anode comprising:
a catalyst comprising Pt, the catalyst having surface area;
an oxygen evolution reaction catalyst on a portion of the surface area of the catalyst comprising Pt; and
at least one of Au, a refractory metal, a refractory metal boride, a refractory metal carbide, a refractory metal nitride, or a refractory metal silicide on a portion of the surface area of the catalyst comprising Pt, wherein the refractory is one of a refractory metal, a refractory metal boride, a refractory metal carbide, a refractory metal nitride, or a refractory metal silicide is independently selected from the group consisting of Hf, Nb, Os, Re, Rh, Ta, Ti, W, Zr, and combinations thereof,
wherein a portion of the surface area of the catalyst comprising Pt is not covered by either the oxygen evolution reaction catalyst or collectively the Au, the refractory metal, refractory metal boride, refractory metal carbide, refractory metal nitride, and refractory metal silicide to the extent present.

2. (canceled)

3. The hydrogen fuel cell anode of claim 1, wherein Pt present in the catalyst comprising Pt is present as at least one of metallic Pt or Pt compound, and wherein the catalyst comprising Pt further comprises at least one of Ir, Ru, or Pd.

4. The hydrogen fuel cell of claim 1, wherein at least some of the least one of Ir, Ru, or Pd is present in at least one organometallic compound, and wherein at least some of the least one of Ir, Ru, or Pd is present in at least one organometallic complex.

5. The hydrogen fuel cell of claim 4, wherein at one organometallic compound present is one of an oxide or a hydrated oxide.

6. The hydrogen fuel cell anode of claim 1, wherein the Pt is present in a range from 0.5 microgram/cm² to 100 micrograms/cm².

7. The hydrogen fuel cell of claim 1, wherein the oxygen evolution reaction catalyst is present in a range from 0.5 microgram/cm² to 250 micrograms/cm².

8. The hydrogen fuel cell of claim 1, wherein the one Au, refractory metal, refractory metal carbide, refractory metal carbide, refractory metal nitride, and refractory metal silicide, to the extent present, is collectively present in a range from 0.5 microgram/cm² to 100 micrograms/cm².

9. The hydrogen fuel cell of claim 1, wherein the oxygen evolution reaction catalyst and the Au, refractory metal, refractory metal carbide, refractory metal carbide, refractory metal nitride, and refractory metal silicide, to the extent present, collectively cover in a range from 2 percent to not greater than 95 percent of the surface area of the catalyst comprising Pt.

10. The hydrogen fuel cell of claim 1, wherein a portion of the oxygen evolution reaction catalyst is covered by the at least one of Au, a refractory metal, a refractory metal boride, a refractory metal carbide, a refractory metal nitride, or a refractory metal silicide.

11. The hydrogen fuel cell of claim 1, wherein a portion of the at least one of Au, a refractory metal, a refractory metal boride, a refractory metal carbide, a refractory metal nitride, or a refractory metal silicide is covered by a portion of the oxygen evolution reaction catalyst.

12. A method of making the hydrogen fuel cell anode of claim 1, the method comprising:
depositing the catalyst comprising Pt via a deposition technique selected from the group consisting of sputtering, atomic layer deposition, molecular organic chemical vapor deposition, molecular beam epitaxy, ion soft landing, thermal physical vapor deposition, vacuum deposition by electrospray ionization, and pulse laser deposition;
depositing the oxygen evolution reaction catalyst via a deposition technique independently selected from the group consisting of sputtering, atomic layer deposition, molecular organic chemical vapor deposition, molecular beam epitaxy, ion soft landing, thermal physical vapor deposition, vacuum deposition by electrospray ionization, and pulse laser deposition; and
depositing the catalyst comprising Pt, the oxygen evolution reaction catalyst, and the at least one of Au, a refractory metal, a refractory metal boride, a refractory metal carbide, a refractory metal nitride, or a refractory metal silicide are conducted under the same vacuum.

13. (canceled)
